(19) United States
(12) Patent Application Publication
(10) Pub. No.: US 2020/0303169 A1
(43) Pub. Date: Sep. 24, 2020

(54) PLASMA PROCESSING METHOD AND PLASMA PROCESSING APPARATUS

(71) Applicant: Tokyo Electron Limited, Tokyo (JP)

(72) Inventor: Hisanori SAKAI, Miyagi (JP)

(21) Appl. No.: 16/819,422

(22) Filed: Mar. 16, 2020

(30) Foreign Application Priority Data
Mar. 20, 2019 (JP) 2019-053837

(51) Int. Cl. H01J 37/32; H01L 21/66; H01L 21/67; G01J 3/443

(52) U.S. Cl. CPC H01J 37/32477; H01L 22/26; H01L 21/67069; H01J 2237/334; G01J 3/443; H01J 2237/2445; H01J 2237/24585; H01J 37/32862

(57) ABSTRACT

There is provision of a plasma processing method using a detector configured to measure emission intensity of a plasma in a plasma processing apparatus. The method includes detecting a first plasma emission intensity that is an intensity of first light incident on the detector through a plasma generating region; detecting at least one second plasma emission intensity that is an intensity of second light incident on the detector from an inner wall of the plasma processing apparatus, without passing through the plasma generating region; and determining a state of the inner wall of the plasma processing apparatus based on a difference between the first plasma emission intensity and the second plasma emission intensity, or based on a ratio between the first plasma emission intensity and the second plasma emission intensity.

### CROSS-REFERENCE TO RELATED APPLICATIONS

This patent application is based on and claims priority to Japanese Patent Application No. 2019-053837 filed on Mar. 20, 2019, the entire contents of which are incorporated herein by reference.

### TECHNICAL FIELD

The present disclosure relates to a plasma processing method and a plasma processing apparatus.

### BACKGROUND

There is known a dry etching device that detects an endpoint of etching based on a change in emission intensity of the plasma. For example, Patent Document 1 describes a dry etching device including a first detector for measuring emission intensity of a plasma in the vicinity of a semiconductor substrate and a second detector for measuring emission intensity of a plasma in the vicinity of a material to be etched that is placed on a first electrode. Patent Document 1 proposes that the emission intensity measured by the first detector and the emission intensity measured by the second detector are calculated, and that an endpoint of etching is detected by a change in the calculation result.

### CITATION LIST

### Patent Document

[Patent Document 1] Japanese Laid-open Patent Application Publication No. 09-055367

### SUMMARY

In optical emission spectroscopy (OES), a state of a plasma can be detected by measuring emission intensity of the plasma. A plasma is affected by a state of an inner wall of a plasma processing apparatus. Therefore, it is important to control the state of the inner wall of the plasma processing apparatus.

The present disclosure provides a plasma processing method and a plasma processing apparatus capable of accurately determining a state of an inner wall of a plasma processing apparatus.

According to one aspect of the present disclosure, there is provision of a plasma processing method using a detector configured to measure emission intensity of a plasma in a plasma processing apparatus. The method includes detecting a first plasma emission intensity that is an intensity of first light incident on the detector through a plasma generating region; detecting at least one second plasma emission intensity that is an intensity of second light incident on the detector from an inner wall of the plasma processing apparatus, without passing through the plasma generating region; and determining a state of the inner wall of the plasma processing apparatus based on a difference between the first plasma emission intensity and the second plasma emission intensity, or based on a ratio between the first plasma emission intensity and the second plasma emission intensity.

### BRIEF DESCRIPTION OF THE DRAWINGS

FIGS. 1A and 1B are cross-sectional diagrams each illustrating a plasma processing apparatus according to an embodiment;

FIG. 2 is a diagram illustrating an example of a detector according to the embodiment;

FIG. 3 is a view illustrating an example of a detection result according to the embodiment;

FIGS. 4A and 4B are diagrams illustrating differences (wall condition) in emission intensity according to the embodiment;

FIG. 5 is a flowchart illustrating a measurement process of plasma emission intensity according to the embodiment;

FIG. 6 is a flowchart illustrating a seasoning process according to the embodiment;

FIG. 7 is a view illustrating how to determine initiation and termination of conditioning according to the embodiment;

FIG. 8 is a flowchart illustrating a dry cleaning process according to the embodiment;

FIG. 9 is a flowchart illustrating a dry cleaning process according to a first variation of the embodiment;

FIG. 10 is a diagram illustrating an example of a detector according to the first variation of the embodiment; and

FIG. 11 is a flowchart illustrating a seasoning process according to a second variation of the embodiment.

### DETAILED DESCRIPTION OF EMBODIMENTS

Hereinafter, embodiments for carrying out the present disclosure will be described with reference to the drawings. In each drawing, the same components are indicated by the same reference numerals and overlapping descriptions may be omitted.

### [Plasma Processing Apparatus]

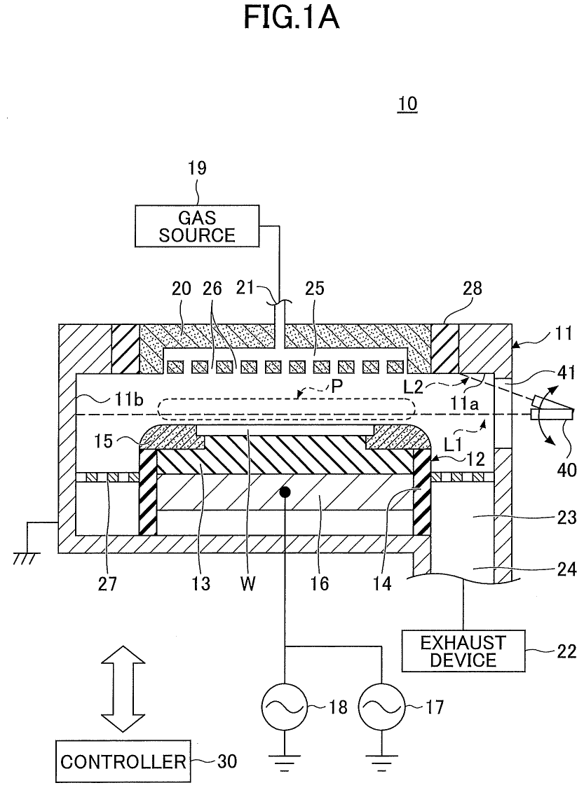

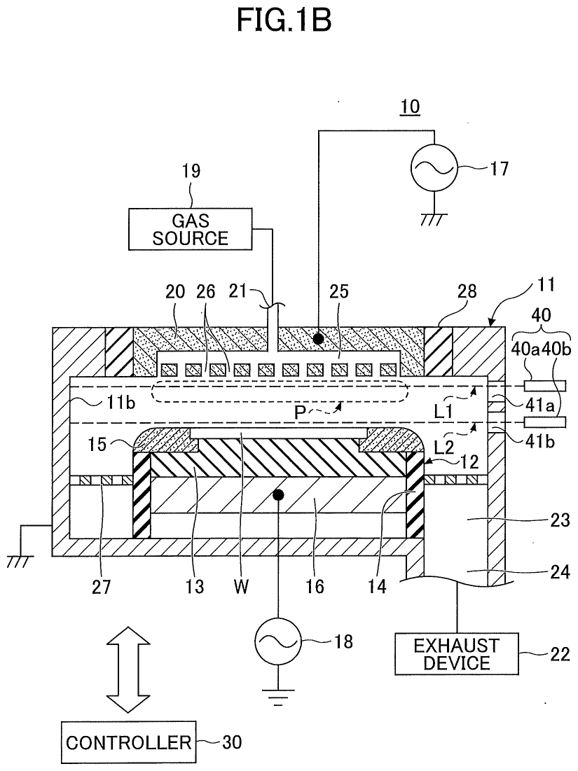

First, a plasma processing apparatus 10 that performs a plasma processing method according to an embodiment will be described with reference to FIG. 1. FIG. 1A and FIG. 1B illustrate cross-sectional schematic views of a parallel plate type capacitive coupling (CCP) plasma processing apparatus, as an example of a plasma processing apparatus 10 according to the present embodiment.

First, a configuration of the plasma processing apparatus 10 illustrated in FIG. 1A will be described. The plasma processing apparatus 10 includes a processing vessel 11 and a stage 12 disposed therein. The processing vessel 11 is a cylindrical container. The processing vessel 11 is, for example, made of aluminum with an alumite-treated (anodized) surface, and is grounded. The stage 12 has a base 16 and an electrostatic chuck 13 disposed on the base 16. The stage 12 is disposed at the bottom of the processing vessel 11 via a support 14 formed of an insulating member.

The base 16 is formed of aluminum or the like. The electrostatic chuck 13 is formed of a dielectric material such as alumina (Al₂O₃), and has a mechanism for holding a wafer W with electrostatic attracting force. In the electrostatic chuck 13, a wafer W is placed in the center, and an annular edge ring 15 (also referred to as a focus ring) surrounding the wafer W is placed in the outer circumference.

An annular exhaust path 23 is formed between a side wall of the processing vessel 11 and a side wall of the stage 12, and the exhaust path 23 is connected to the exhaust device 22 via an exhaust port 24. The exhaust device 22 includes a vacuum pump such as a turbomolecular pump or a dry pump. The exhaust device 22 directs a gas in the processing vessel 11 to the exhaust path 23 and the exhaust port 24, and evacuates the gas. This reduces pressure of a processing space in the processing vessel 11 to a predetermined quality of vacuum.

The exhaust path 23 is provided with a baffle plate 27 that separates the processing space from an exhaust space and that controls a flow of gas. The baffle plate 27 is an annular member coated with, for example, a corrosion-resistant film (e.g., yttrium oxide (Y₂O₃)) on a surface of a base material formed of aluminum, and multiple through-holes are formed in the baffle plate 27.

The stage 12 is connected to a first radio frequency power supply 17 and a second radio frequency power supply 18. The first radio frequency power supply 17 applies, for example, 60 MHz of radio frequency electric power for plasma generation (hereinafter referred to as “HF power”) to the stage 12. The second radio frequency power supply 18 applies, for example, 40 MHz of radio frequency electric power for attracting ions (hereinafter referred to as “LF power”) to the stage 12. Thus, the stage 12 also functions as a lower electrode.

At an opening of a ceiling of the processing vessel 11, a showerhead 20 is provided via a ring-shaped insulating member 28 attached to a circumference of the showerhead 20. HF power is applied capacitively between the stage 12 and the showerhead 20, and a gas is formed into a plasma by the HF power primarily.

The ions in the plasma are drawn into the stage 12 by LF power applied to the stage 12, and a wafer W placed on the stage 12 is bombarded with the ions. Accordingly, a predetermined film on the wafer W is efficiently processed (e.g., etched).

The gas source 19 supplies a gas according to a process condition of each plasma process, such as an etching process, a cleaning process, and a seasoning process. The gas enters the showerhead 20 via a gas line 21, passes through a gas diffusion chamber 25, and is introduced into the processing vessel 11 in a form of a shower from a large number of gas holes 26.

The plasma processing apparatus 10 illustrated in FIG. 1B has substantially the same configuration as the plasma processing apparatus 10 illustrated in FIG. 1A, but arrangement of the first radio frequency power supply 17 and a configuration of a detector 40 to be described below are different. In the plasma processing apparatus 10 illustrated in FIG. 1B, the first radio frequency power supply 17 is connected to the showerhead 20. The first radio frequency power supply 17 applies, for example, 60 MHz of HF power to the showerhead 20.

The controller 30 includes a CPU (Central Processing Unit), a ROM (Read Only Memory), and a RAM (Random Access Memory). By the CPU executing a program stored in the RAM or the ROM, the controller 30 controls various components in the plasma processing apparatus 10. The controller 30 controls various plasma processing and an entire apparatus, in accordance with procedures set in a recipe stored in the RAM.

When performing plasma processing in the plasma processing apparatus 10 of the above-described configuration, a wafer W is first loaded into the processing vessel 11 from a gate valve (not illustrated), while the wafer W is held on a transport arm. The wafer W is placed on the electrostatic chuck 13. The gate valve is closed after the wafer W is loaded. By applying DC voltage to an electrode (not illustrated) of the electrostatic chuck 13, the wafer W is attracted and held to the electrostatic chuck 13 by Coulomb force.

Pressure in the processing vessel 11 is reduced to a set value by the exhaust device 22, and the interior of the processing vessel 11 is controlled to be in a vacuum state. A predetermined gas is introduced into the processing vessel 11 from the showerhead 20 in a form of a shower. HF power and LF power are applied to the stage 12. In FIG. 1A, because the HF power is applied to the stage 12, a plasma generating region P is in the vicinity of the wafer W. In FIG. 1B, because the HF power is applied to the showerhead 20, the plasma generating region P is in the vicinity of the showerhead 20.

A plasma is generated from the introduced gas, mainly by the HF power, and plasma processing such as etching is applied to the wafer W by the plasma. After the plasma processing is completed, the wafer W is held on the transfer arm and is unloaded to the outside of the processing vessel 11. By repeating this process, wafers W are processed consecutively.

Light emitted within the processing vessel 11 during plasma processing of wafer W is incident on the detector 40 via a window 41 provided at the side wall.

The detector 40 illustrated in FIG. 1A detects light incident along an optical axis of an optical system of the detector 40. As the detector 40 can change a direction of the optical axis of the optical system, the detector 40 can detect light incident from different directions. In a case in which the optical axis of the optical system of the detector 40 is a dashed line L1 (hereinafter referred to as a “first optical axis L1”) illustrated in FIG. 1A, the detector 40 detects light incident from the processing vessel 11 along the first optical axis L1. In a case in which the optical axis of the optical system of the detector 40 is a dashed line L2 (hereinafter referred to as an “optical axis L2”) illustrated in FIG. 1A, the detector 40 detects light incident from the processing vessel 11 along the optical axis L2. Light incident along the first optical axis L1 passes through the plasma generating region P near the wafer W. After the detector 40 finishes detecting light incident along the first optical axis L1, the detector 40 changes a direction of the optical axis from the first optical axis L1 to the optical axis L2, and the detector 40 detects light incident along the second optical axis L2. As illustrated in FIG. 1A, the second optical axis L2 is directed to a ceiling wall 11a of the processing vessel 11 without passing through the plasma generating region P.

In FIG. 1B, the detector 40 includes a detector 40a and a detector 40b. The detectors 40a and 40b do not have functions to change directions of optical axes of optical systems of the detectors 40a and 40b, respectively. A dashed line L1 of FIG. 1B indicates the optical axis (hereinafter referred to as a first optical axis L1) of the optical system of the detector 40a, and a dashed line L2 of FIG. 1B indicates the optical axis (hereinafter referred to as a second optical axis L2) of the optical system of the detector 40b. Light incident along the first optical axis L1 and light incident along the second optical axis L2 are emitted from the interior of the processing vessel 11, and are detected by the detectors 40a and 40b, by passing through different windows 41a and 41b respectively. However, the plasma processing apparatus 10 illustrated in FIG. 1B may be configured such that both the light may pass through the same window, as illustrated in FIG. 1A.

The detector 40a detects light incident along the first optical axis L1. The first optical axis L1 passes through the plasma generating region P near the showerhead 20, and reaches the side wall lib of the processing vessel 11. The detector 40b detects light incident along the second optical axis L2. The second optical axis L2 reaches the side wall 11b of the processing vessel 11 without passing through the plasma generating region P.

The detector 40 monitors a state of a plasma using OES. In OES, elements in a material are vaporized and excited by a discharge plasma, and wavelengths of emission line spectra (atomic spectra) each of which is unique in each element are qualitatively determined, and intensity of the emission lines is determined quantitatively. However, OES is an example of a technique for monitoring a state of a plasma, and the detector 40 is not limited to OES as long as the detector 40 can monitor a state of a plasma.

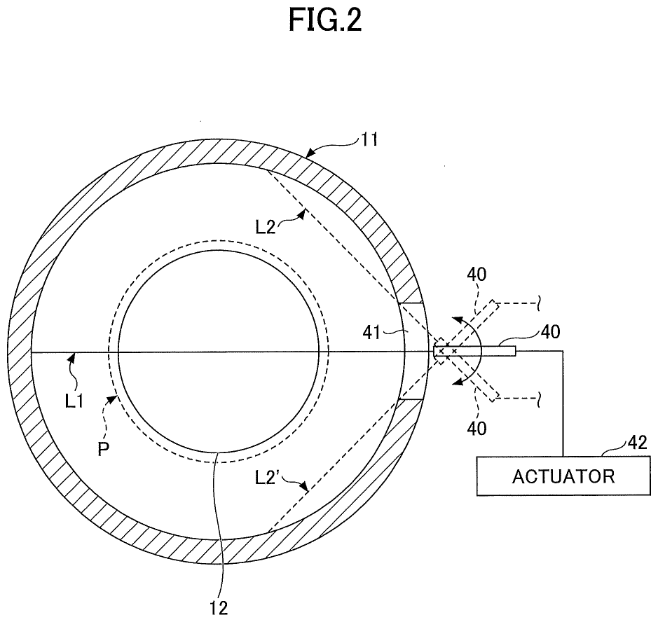

As illustrated in FIG. 2, the detector 40 can change a direction of an optical axis of the detector 40 upward, downward, leftward, rightward, and diagonally by power of an actuator 42. With such a configuration, the detector 40 can change a direction of light to be detected by the detector 40, such as a direction corresponding to a line (first optical axis) L1 and a direction corresponding to a dashed line (second optical axis) L2, as illustrated in FIG. 2. The detector 40 may also change its optical axis to other directions, such as a second dashed line L2′ in FIG. 2. This allows measurement of emission intensity of plasma incident from multiple directions. Also, as will be described later, a state of the inner wall of the processing vessel 11 can be determined based on a difference between plasma emission intensity at multiple locations. In a case in which multiple light beams each of which is incident along a different optical axis are detected through the same window 41, influence of cloudiness or the like of the window 41 can be cancelled in determining the condition of the inner wall using the difference between the plasma emission intensities at the multiple locations.

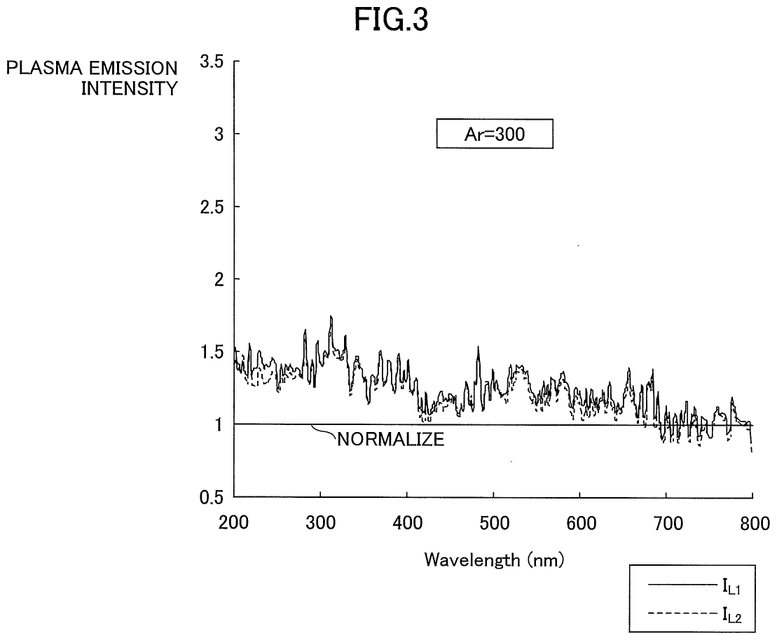

FIG. 3 illustrates a result of measuring emission spectra of light incident along the line L1 illustrated in FIG. 2 and light incident along the dashed line L2 illustrated in FIG. 2, while argon gas is supplied into the processing vessel 11 at a predetermined flow rate. A line labeled as “I_{L1}” indicates the emission spectrum of light incident along the line L1 in FIG. 2, and a dashed line labeled as “I_{L2}” indicates the emission spectrum of light incident along the dashed line L2 in FIG. 2. Note that the emission spectra in FIG. 3 are normalized by emission intensity of light that is measured while argon gas is supplied into the processing vessel 11 at another flow rate. According to FIG. 3, there was no significant difference between a state of the plasma at the center of the processing vessel 11 measured by the light incident along the line L1, and a state of the plasma close to the inner surface of the processing vessel 11 measured by the light incident along the line L2. That is, it was found that the measurement results of the state of the plasma at the center of the processing vessel 11 and the measurement results of the state of the plasma at the inner end of the processing vessel 11 were affected by disturbance to the same degree.

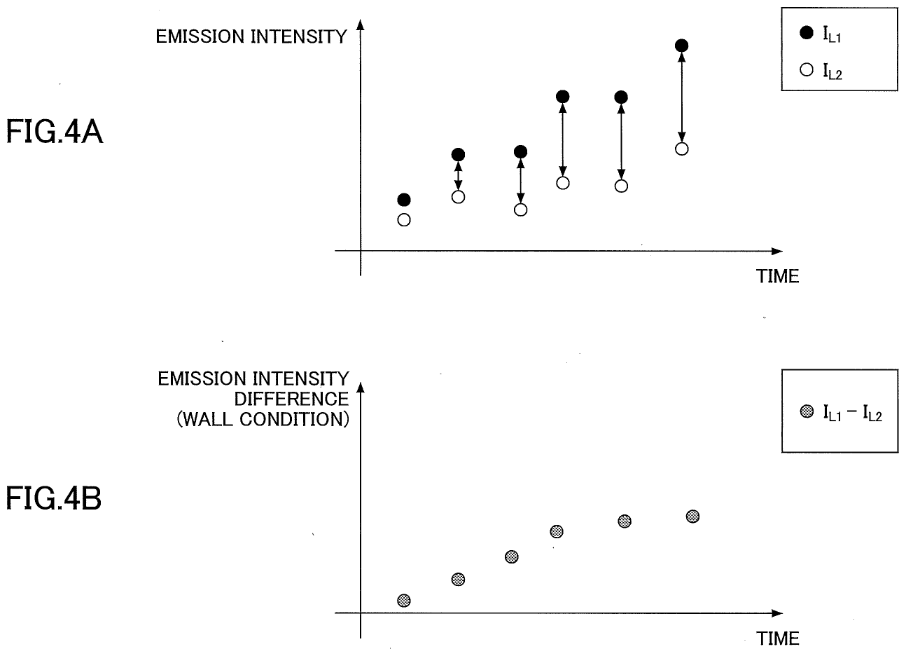

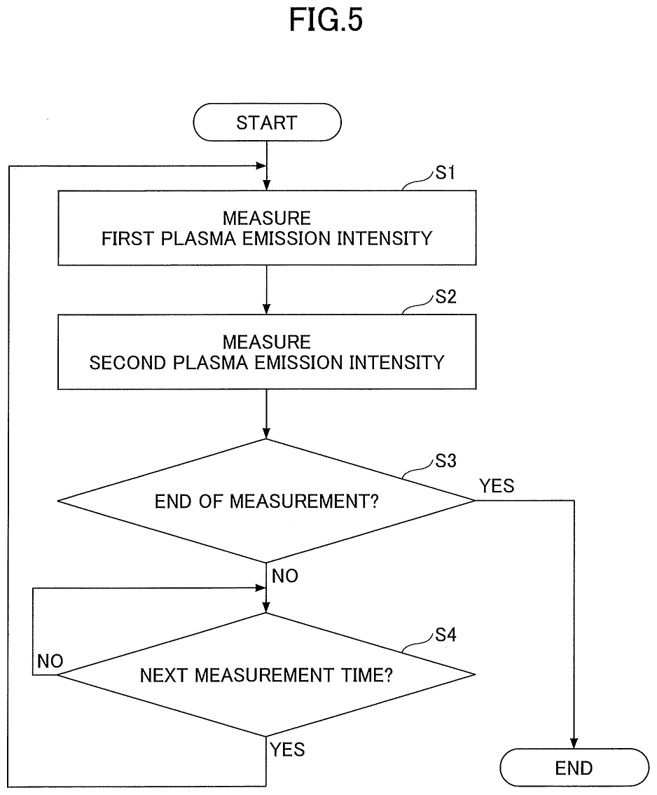

Therefore, a difference between emission intensity of a predetermined wavelength of light incident along the first optical axis L1 (hereinafter referred to as “first emission intensity”; each filled circle (IL′) in FIG. 4A indicates the first emission intensity) and emission intensity of a predetermined wavelength of light incident along the second optical axis L2 at the same timing (hereinafter referred to as “second emission intensity”; each white circle (I_{L2}) in FIG. 4A indicates the second emission intensity) is calculated periodically. In the example of FIG. 2, the first optical axis L1 passes through the plasma generating region P. Thus, the first emission intensity of light incident along the first optical axis L1 (filled circles (I_{L1})) indicates states of a plasma in the plasma generating region P.

Meanwhile, the second optical axis L2 reaches the ceiling wall of the processing vessel 11 without passing through the plasma generating region P. Thus, the second emission intensity of light incident along the second optical axis L2 (white circles (I_{L2})) indicates a state of a plasma diffused from the plasma generating region P and a state of the inner wall of the processing vessel 11.

Thus, by calculating the difference between the first emission intensity and the second emission intensity indicated by arrows in FIG. 4A, the state of the plasma and the disturbance can be cancelled as factors. That is, the state of the inner wall of the processing vessel 11 can be determined based on the difference between the first and second emission intensity (circles “I_{L1}-I_{L2}” filled with dotted patterns in FIG. 4B).

### [Measurement Process of Plasma Emission Intensity]

Hereinafter, a measurement process of plasma emission intensity for determining the state of the wall will be described with reference to FIG. 5. FIG. 5 is a flow chart illustrating the measurement process of plasma emission intensity according to the present embodiment.

In the present embodiment, while a plasma is generated in the processing vessel 11, the detector 40 measures intensity of a predetermined wavelength component in an optical spectrum of plasma light, by optical emission spectroscopy (OES). As described above, intensity of multiple light incident from different directions (or locations), such as light incident along the first optical axis L1 and light incident along the second optical axis L2 (in FIG. 1A or 1B), are detected by the detector 40. In the following description, intensity of light incident along the first optical axis L1 may be referred to as “first plasma emission intensity”, and intensity of light incident along the second optical axis L2 may be referred to as “second plasma emission intensity”. When the measurement process is initiated, the detector 40 measures the first plasma emission intensity using light incident along the first optical axis L1 passing through the plasma generating region P, based on OES (step S1). Next, the detector 40 measures the second plasma emission intensity using light incident along the second optical axis L2 that does not pass through the plasma generating region P, based on OES (step S2).

Next, in step S3, the controller 30 determines whether or not to terminate the measurement process. If it is determined that the measurement process is to be terminated, the controller 30 terminates the measurement process. If it is determined that the measurement should not be terminated in step S3, the controller 30 determines whether or not it is time for the next measurement (step S4). The controller 30 waits until the next measurement time comes. If it is determined that it is the time for the next measurement (YES in step S4), the measurement process returns to step S1, and the measurement of the first plasma emission intensity and the next second plasma emission intensity is performed again in steps S1 and thereafter. Because steps S1 to S4 are repeated until the measurement process terminates, the first and second plasma emission intensities are measured at predetermined intervals. The first and second plasma emission intensities measured at the predetermined intervals are transmitted to the controller 30.

### [Seasoning Control Process]

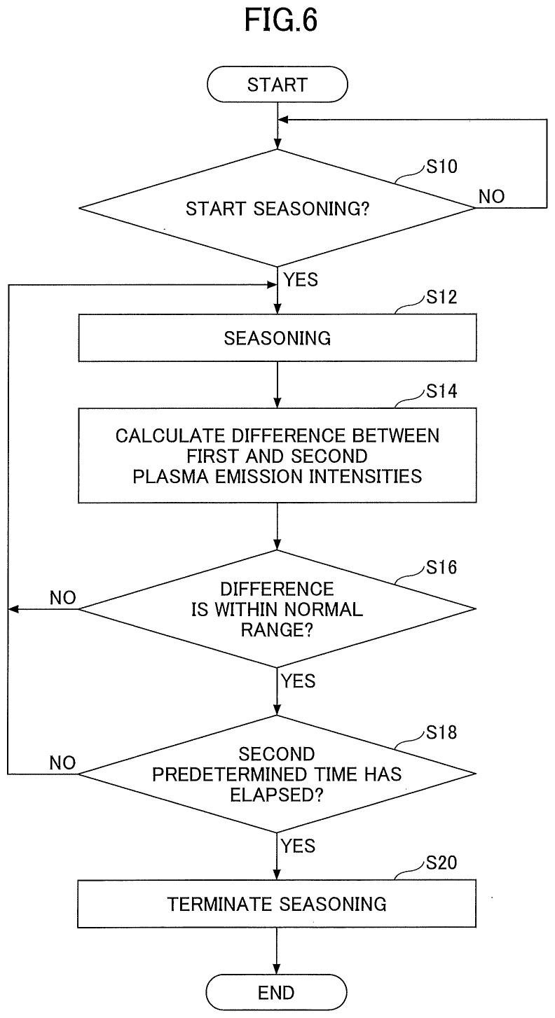

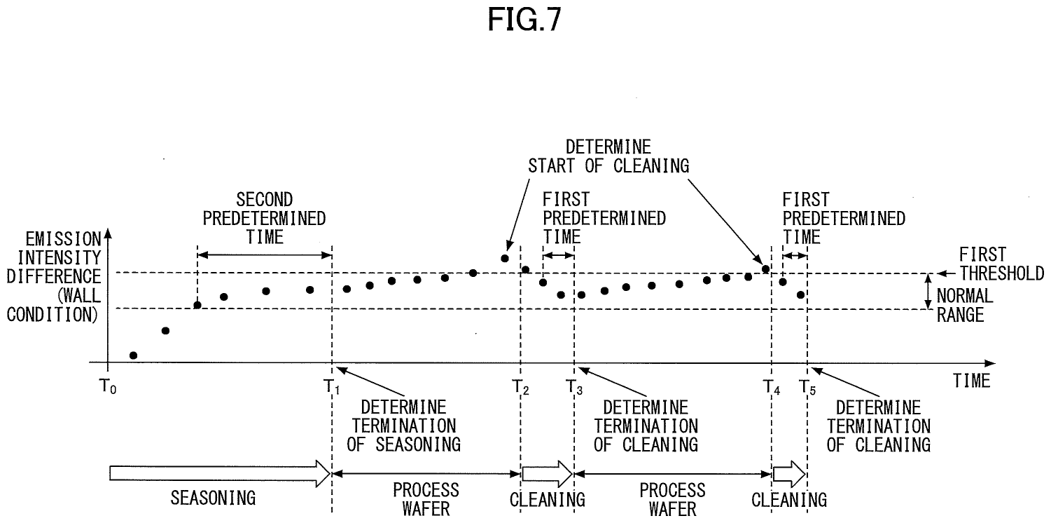

Next, a seasoning control process using a difference between the first plasma emission intensity and the next second plasma emission intensity will be described with reference to FIGS. 6 and 7. FIG. 6 is a flowchart illustrating the seasoning control process according to the present embodiment. FIG. 7 is a diagram illustrating the beginning and end of conditioning according to the present embodiment. Hereinafter, as examples of the conditioning, seasoning and dry cleaning will be described. The horizontal axis of FIG. 7 indicates time, but may indicate the number of wafers (product wafers or dummy wafers).

When the seasoning control process (the process of FIG. 6) is started, the controller 30 determines whether or not to start seasoning (step S10). FIG. 7 describes an example in which the seasoning starts at predetermined time T₀. Accordingly, the controller 30 determines that the seasoning is started when the time T₀ comes (YES in step S10), and executes the seasoning in the processing vessel (step S12). If seasoning is already being executed, the controller 30 continues the seasoning. During the seasoning, to stabilize the interior of the processing vessel 11, a plasma is generated under the same process condition as a condition of a wafer process, and a plasma process is performed within the processing vessel 11.

During the seasoning, the first and second plasma emission intensities measured at the detector 40 is sent to the controller 30 at the predetermined intervals. As illustrated in FIG. 6, the controller 30 acquires a measurement value of the first plasma emission intensity and a measurement value of the second plasma emission intensity, and calculates a difference between the measurement value of the first plasma emission intensity and the measurement value of the second plasma emission intensity (step S14).

Next, in step S16, the controller 30 determines whether the calculated difference is within a normal range. Each filled circle in FIG. 7 indicates magnitude of the difference between the first plasma emission intensity and the second plasma emission intensity (hereinafter simply referred to as a “difference”) and the time when the difference is calculated. Also, in FIG. 7, the normal range corresponds to an area between two horizontal dashed lines. Thus, the leftmost filled circle in FIG. 7 indicates magnitude of the difference calculated for the first time. As illustrated in FIG. 7, differences calculated at first and second times during the seasoning are plotted outside the normal range. Meanwhile, differences calculated at third to sixth times during the seasoning are plotted within the normal range.

If it is determined the difference calculated in step S14 is outside the normal range (NO in step S16), the process of FIG. 6 returns to step S12 to continue the seasoning. Meanwhile, if it is determined the difference calculated in step S14 is within the normal range (YES in step S16), the process of FIG. 6 proceeds to step S18. In a case in which the measured differences are as illustrated in FIG. 7, with respect to first and second determination in step S16, the controller 30 determines that the differences calculated at the first and second times are outside the normal range. Thus, the process of FIG. 6 returns to step S12, and continues the seasoning. Meanwhile, with respect to third to sixth determination in step S16, the controller 30 determines that the difference calculated at third to sixth times is within the normal range, and the process of FIG. 6 proceeds to step S18.

In step S18, the controller 30 determines whether or not a second predetermined period of time has elapsed since the difference became within the normal range for the first time. In a case in which the measured differences are as illustrated in FIG. 7, when the difference was calculated for the third intensity measurement (i.e., the third filled circle), the difference became within the normal range for the first time. The second predetermined period of time is a predetermined value in which it is determined that an environment inside the processing vessel 11 has been stabilized in a normal state by performing seasoning.

If it is determined that the second predetermined period of time has not elapsed since the difference became within the normal range for the first time (NO in step S18), the controller 30 performs steps S12 to S18 again. In a case in which the measured differences are as illustrated in FIG. 7, before time T₁, the controller 30 determines that the second predetermined period of time has not elapsed since the difference became within the normal range for the first time.

Meanwhile, if it is determined that the second predetermined period of time has elapsed since the difference became within the normal range for the first time (YES in step S18), the controller 30 terminates seasoning (step S20), and terminates the process of FIG. 6. In the example of FIG. 7, a determination to terminate seasoning is made at time T₁.

The above-described process determines whether a state of the inner wall of the processing vessel 11 is in the normal range, based on the difference between the first plasma emission intensity and the second plasma emission intensity. Then, based on the determination result, if it is determined that the state of the inner wall of the processing vessel 11 has been stabilized in the normal state, the controller 30 determines that seasoning should be terminated.

### [Dry Cleaning Control Process]

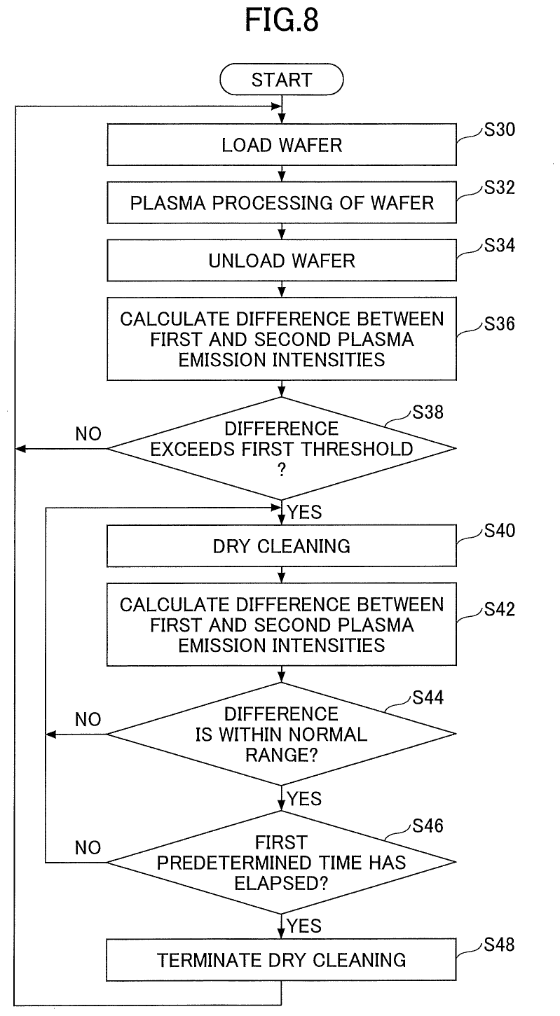

Next, a dry cleaning control process using the difference between the first plasma emission intensity and the second plasma emission intensity will be described with reference to FIGS. 8 and 7. FIG. 8 is a flowchart illustrating the dry cleaning control process according to the present embodiment.

When the dry cleaning control process (the process of FIG. 8) is started, the controller 30 controls the transfer arm (not illustrated) to load a wafer W into the processing vessel 11 (step S30). Next, the controller 30 applies HF power and LF power based on process conditions set in the recipe, supplies a predetermined gas to generate a plasma, and applies a plasma process to the wafer W (step S32).

Next, after the plasma processing, the controller 30 controls the transfer arm (not illustrated) to unload the wafer W from the processing vessel 11 (step S34). Next, the controller 30 acquires respective measurement values of the first plasma emission intensity and the second plasma emission intensity, and calculates a difference between the first plasma emission intensity and the second plasma emission intensity (step S36). In step S38, the controller 30 determines whether the difference between the first plasma emission intensity and the second plasma emission intensity exceeds a first threshold value. The first threshold is a preset value, which is set to a value determined to require dry cleaning due to aggravation of the wall condition in the processing vessel 11, such as adhesion of deposits on the walls.

If it is determined that the difference does not exceed the first threshold value in step S38, the controller 30 determines that it is not necessary to start dry cleaning in the processing vessel 11 including the inner wall, and the process of FIG. 8 returns to step S30. The controller 30 loads a next wafer W in the processing vessel 11, and repeats a process in steps S32 to S38.

If it is determined that the difference exceeds the first threshold value in step S38, the controller 30 executes dry cleaning (step S40). If the dry cleaning is already being executed, the controller 30 continues the dry cleaning.

In the example of FIG. 7, the first threshold value is set to an upper limit of the above-described normal range. In this case, processing of wafers W is performed until the difference exceeds the first threshold value.

In FIG. 7, the difference exceeds the first threshold at the time just before time T₂, for example. Therefore, it is determined that dry cleaning should be started at this time point. As a result, in the example of FIG. 7, dry cleaning has started at time T₂.

After step S40, the controller 30 calculates the difference between the first plasma emission intensity and the second plasma emission intensity by performing the same operation as step S36 (step S42). Next, the controller 30 determines whether the difference calculated in step S42 is within the normal range (step S44). The controller 30 continues the dry cleaning until the calculated difference becomes within the normal range. If it is determined that the calculated difference is within the normal range in step S44, the controller 30 determines whether or not a first predetermined period of time has elapsed since the difference became within the normal range for the first time (step S46).

The first predetermined period of time is a predetermined value, in which it is determined that the environment inside the processing vessel 11 has been stabilized in a normal state by dry cleaning.

If it is determined that the first predetermined period of time has not elapsed since the difference became within the normal range for the first time (NO in step S46), the controller 30 repeats a process in steps S40 to S46.

Meanwhile, if it is determined that the first predetermined period of time has elapsed since the difference became within the normal range (YES in step S46), the controller 30 terminates dry cleaning (step S48). Then, the process of FIG. 8 returns step S30, and the controller 30 repeats step S30 and thereafter.

In the example of FIG. 7, dry cleaning is terminated at time T₃, which is a time when a state in which the difference between the first plasma emission intensity and the second plasma emission intensity is within the normal range has been continued for the first predetermined period of time, after the difference between the first plasma emission intensity and the second plasma emission intensity had exceeded the first threshold value and since the difference had returned to the normal range for the first time.

As a result, next wafers W are processed during the time between T₃ and T₄ in FIG. 7. When the difference between the first plasma emission intensity and the second plasma emission intensity exceeds the first threshold value again (just before time T₄ in FIG. 7), it is determined that dry cleaning is necessary, and dry cleaning is started at time T₄.

In the example of FIG. 8, a wafer W was processed immediately after completion of the dry cleaning, but this is not limited thereto. For example, a predetermined film may be pre-coated for a predetermined period of time after completion of dry cleaning, and processing of wafer W may be performed after the pre-coating.

As described above, in the plasma processing according to the present embodiment, the condition of the wall in the processing vessel 11 is determined based on the difference between the first plasma emission intensity indicating a state of a plasma and the second plasma emission intensity indicating a state of the plasma and the wall. This allows termination of seasoning, start of dry cleaning, and termination of dry cleaning to be performed in a timely manner based on the condition of the wall. This can avoid decrease in productivity of wafer processing due to deterioration of the environment in the processing vessel 11, such as generation of particles in the processing vessel 11.

[First Variation]

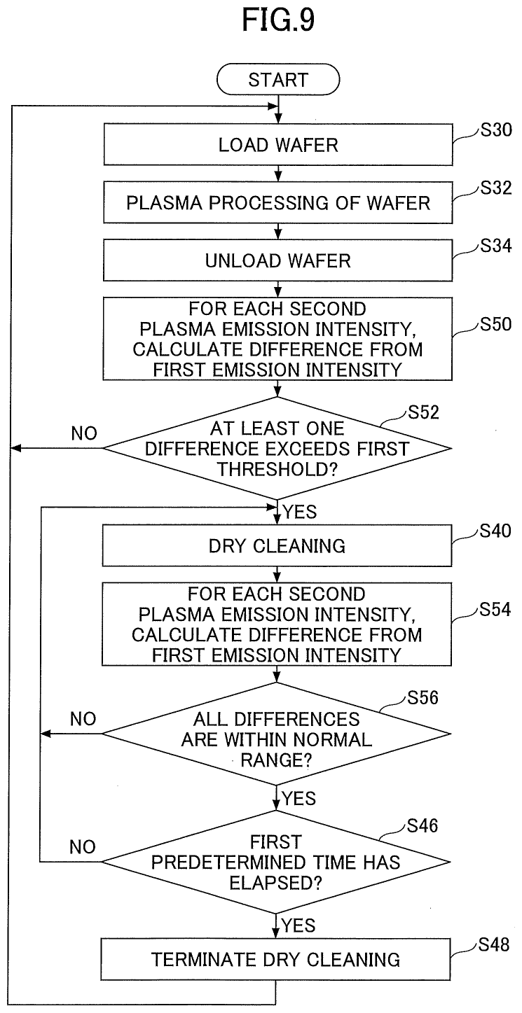

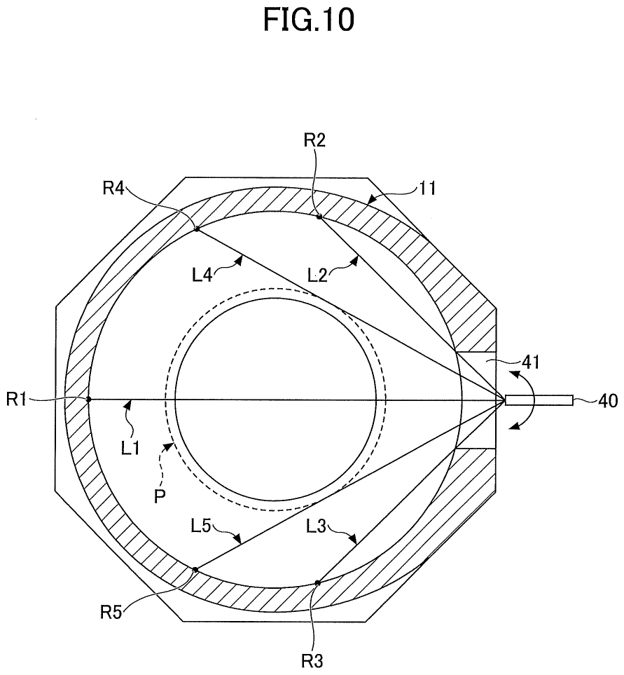

Next, a dry cleaning control process according to a first variation of the present embodiment will be described with reference to FIGS. 9 and 10. FIG. 9 is a flowchart illustrating the dry cleaning control process according to the first variation of the present embodiment. FIG. 10 is a diagram illustrating an example of the detector 40 according to the first variation of the present embodiment. Among steps of the dry cleaning control process according to the first variation of FIG. 9, the same step numbers are assigned to the steps of performing the same process as the dry cleaning control process of FIG. 8.

As illustrated in FIG. 10, in the dry cleaning control process according to the first variation, the controller 30 detects three or more types of light incident from different directions using the detector 40, while changing a direction of an optical axis of the detector 40. The directions from which the detector 40 detects incident light may be chosen such that the detector 40 can detect light coming from multiple points on the inner wall of the processing vessel 11 each of which are evenly distributed in a circumferential direction of the processing vessel 11. In the example of FIG. 10, five types of light each coming from a different direction is detected. Lines L1 to L5 illustrated in FIG. 10 indicate optical axes of the detector 40, and the detector 40 according to the first variation of the present embodiment detects five types of light incident along these five optical axes (L1 to L5). The first optical axis L1 passes through the plasma generating region P. Intensity of light incident on the detector 40 along the first optical axis L1 is used to measure (estimate) a state of a plasma, that is, the intensity of light incident on the detector 40 along the first optical axis L1 corresponds to the above-described first plasma emission intensity. Meanwhile the second optical axes L2 to L5 extend from the detector 40 to the side wall of the processing vessel 11 without passing through the plasma generating region P. Intensity of light incident on the detector 40 along each of the second optical axes L2 to L5 is used to measure (estimate) states of the inner wall of the processing vessel 11, that is, the intensity of light incident on the detector 40 along each of the second optical axes L2 to L5 corresponds to the second plasma emission intensity. In the description of the first variation, the intensity of light incident on the detector 40 along the first optical axis L1 is also referred to as the first plasma emission intensity, and the intensity of light incident on the detector 40 along each of the second optical axes L2 to L5 is referred to as the second plasma emission intensity. It should be noted that multiple detectors 40 may be used to detect light coming from different directions, instead of changing a direction of the optical axis of a single detector 40.

When the process of FIG. 9 is started, wafer processing is performed in steps S30 to S34. Next, the controller 30 acquires the measurement value of the first plasma emission intensity measured using light incident on the detector 40 along the first optical axis L1 and the respective measurement values of the second plasma emission intensities measured using light incident on the detector 40 along the second optical axes L2 to L5 (step S50). Also, in step S50, for each of the measurement values of the second plasma emission intensities, the controller 30 calculates a difference from the first plasma emission intensity. By performing step S50, multiple differences, each of which is a difference between the first plasma emission intensity and a corresponding one of the second plasma emission intensities, are calculated.

Next, the controller 30 determines whether or not at least one of the calculated differences exceeds the first threshold value (step S52). If it is determined that none of the calculated differences exceeds the first threshold value, the controller 30 determines that it is not necessary to start dry cleaning. In such a case, the process returns to step S30, and the controller 30 repeats steps S32 to S34, S50, and S52.

If it is determined that at least one of the calculated differences exceeds the first threshold value in step S52, the controller 30 executes dry cleaning (step S40). Subsequently, in step S54, the controller 30 performs the same operation as step S50. That is, the controller 30 acquires the measurement value of the first plasma emission intensity and the respective measurement values of the second plasma emission intensities, and calculates, for each of the measurement values of the second plasma emission intensities, the difference from the first plasma emission intensity.

Next, in step S56, the controller 30 determines whether all of the differences calculated in step S54 are within the normal range. If all of the calculated differences are within the normal range, it can be determined that the status of the side wall the processing vessel 11 is normal at all of the multiple points (points R1 to R5 in FIG. 10) in the circumferential direction of the side wall of the processing vessel 11. Thus, by performing step S56, the controller 30 can confirm that the wall condition is uniform in the circumferential direction.

The controller 30 continues the dry cleaning of step S40 until all of the calculated differences become within the normal range. If it is determined that all of the calculated differences are within the normal range in step S56, the controller 30 determines whether or not a first predetermined period of time has elapsed since all the differences became within the normal range for the first time (step S46).

The controller 30 repeats steps S40, S54, S56, and S46 until it is determined that the first predetermined period of time has elapsed since all of the respective differences between the second plasma emission intensities and the first plasma emission intensity became within the normal range for the first time.

If it is determined that the first predetermined period of time has elapsed since all of the differences became within the normal range for the first time (YES in step S46), the controller 30 terminates dry cleaning (step S48). Then, the process returns to step S30, and the controller 30 repeats step S30 and thereafter.

According to the cleaning process according to the first variation described above, it can be checked that the wall condition in the processing vessel 11 is uniform in the circumferential direction. Because uniformity of the state of the wall can be checked in the circumferential direction, dry cleaning can be started and terminated at more appropriate timings. Note that the points at which the state of the wall is measured (e.g., the points of the wall at which the optical axis of the detector 40 is directed) may not be uniform in the circumferential direction of the processing vessel 11. For example, the points at which the optical axis is directed may be interspersed with respect to the side wall and a ceiling wall. Accordingly, the overall condition of the inner wall of the processing vessel 11 can be accurately detected.

Although the cleaning process has been described in the first variation, the above-described process of the first variation is not limited thereto. The above-described process of the first variation can be used for determining timing of termination of seasoning. For example, in step S18 of FIG. 6, the seasoning may be terminated if it is determined that the second predetermined period of time has elapsed after all of the differences described in the first variation became within the normal range for the first time.

[Second Variation]

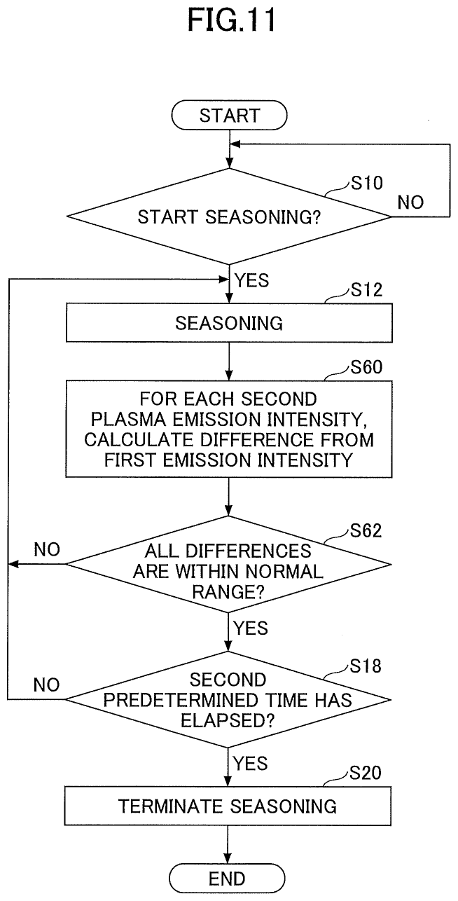

A seasoning process according to a second variation of the present embodiment will be described specifically, with reference to FIG. 11. FIG. 11 is a flowchart illustrating the seasoning process according to the second variation of the present embodiment. Among steps of the seasoning process according to the second variation of FIG. 11, the same step numbers are assigned to the steps of performing the same process as that of FIG. 6.

In the seasoning process according to the second variation, when it is determined that seasoning starts (step S10), the controller 30 performs seasoning in the processing vessel 11 (step S12).

During the seasoning, the controller 30 acquires a measurement value of the first plasma emission intensity measured using light incident along the first optical axis L1 from the detector 40 at a predetermined interval, and acquires respective measurement values of the second plasma emission intensities each measured using light incident along the second optical axes L2 to L5 at a predetermined interval. In step S60, the controller 30 calculates, for each of the acquired second plasma emission intensities, a difference from the acquired first plasma emission intensity. By performing step S60, multiple differences, each of which is a difference between the first plasma emission intensity and a corresponding one of the second plasma emission intensities, are calculated.

Next, in step S62, the controller 30 determines whether or not all of the calculated differences are within the normal range. If it is determined that at least one of the calculated differences is out of the normal range (NO in step S62), the process returns to step S12, and the controller 30 continues the seasoning. Meanwhile, if it is determined that all of the calculated differences are within the normal range (YES in step S62), the process proceeds to step S18.

In step S18, the controller 30 determines whether or not the second predetermined period of time has elapsed since all of the calculated differences became within the normal range for the first time. If it is determined that the second predetermined period of time is not elapsed since all of the calculated differences became within the normal range for the first time, the process returns to step S12, and the controller 30 continues the seasoning.

Meanwhile, if it is determined that the second predetermined period of time has elapsed after all of the calculated differences became within the normal range, the controller 30 terminates the seasoning of the processing vessel 11 (step S20), to terminate the present seasoning process.

According to the seasoning process of the second variation described above, it can be checked that the wall condition of the wall in the processing vessel 11 is uniform in the circumferential direction. Because uniformity of the state of the wall can be checked in the circumferential direction, seasoning can be completed at more appropriate timings.

In the above-described embodiment and its variations, the first plasma emission intensity and the second plasma emission intensity are acquired by measuring intensity of a predetermined wavelength component in an optical spectrum of plasma light using OES. In the above-described embodiment and its variations, wall condition is determined based on a difference (subtraction) between the measured first plasma emission intensity and the measured second plasma emission intensity, but is not limited thereto. For example, a ratio (division) of the first plasma emission intensity to the second plasma emission intensity may be used to determine the wall condition. The ratio (division) of measured first and second plasma emission intensities can normalize a relationship between a state of the wall and a state of a plasma. This allows the state of the wall to be determined based on the normalized relationship between the state of the wall and the state of the plasma.

In the above described embodiment and its variations, a first predetermined period of time and a second predetermined period of time are used, but the number of dummy wafers may be used instead of time. For example, in a case in which a dummy wafer is loaded when performing seasoning and dry cleaning, in step S18 of FIG. 6 or FIG. 11, or in step S46 of FIG. 8 or FIG. 9, determination may be made based on the number of loaded dummy wafers.

The first and second plasma emission intensities may be measured simultaneously, or may be measured at generally consecutive timings.

Further, in the present embodiment and its variations, as examples of a conditioning process in the processing vessel 11, seasoning and dry cleaning have been described, but the present invention is not limited thereto. The conditioning process may include pre-coating to coat a predetermined protective film (SiO₂ film) on the interior of the processing vessel 11. In this case, the protective film may be formed by performing plasma processing under a different condition from the process condition when processing a wafer.

The plasma processing method and the plasma processing apparatus according to the embodiment disclosed herein are to be considered exemplary in all respects and not limiting. The above embodiment and its variations may be modified and enhanced in various forms without departing from the appended claims and the gist thereof. Matters described in the above embodiment and variations thereof may take other configurations to an extent not inconsistent, and may be combined to an extent not inconsistent.

The present disclosure is applicable to any types of plasma processing apparatus, such as an atomic layer deposition (ALD) type, a capacitively coupled plasma (CCP) type, an inductively coupled plasma (ICP) type, a radial line slot antenna type, an electron cyclotron resonance plasma (ECR) type, and a helicon wave plasma (HWP) type.

What is claimed is:

1. A method of performing a plasma process using a detector configured to measure emission intensity of a plasma in a plasma processing apparatus, the method comprising:
detecting a first plasma emission intensity, the first plasma emission intensity being an intensity of first light incident on the detector through a plasma generating region;
detecting at least one second plasma emission intensity, the second plasma emission intensity being an intensity of second light incident on the detector from an inner wall of the plasma processing apparatus without passing through the plasma generating region; and
determining a state of the inner wall of the plasma processing apparatus based on a difference between the first plasma emission intensity and the second plasma emission intensity, or based on a ratio between the first plasma emission intensity and the second plasma emission intensity.

2. The method according to claim 1, wherein the determining of the state of the inner wall includes determining a timing of a start of conditioning in the plasma processing apparatus or a timing of an end of the conditioning, based on the state of the inner wall of the plasma processing apparatus.

3. The method according to claim 2, wherein the conditioning is at least one of dry cleaning, seasoning, and pre-coating.

4. The method according to claim 1, wherein the determining of the state of the inner wall includes
determining that dry cleaning should be started in response to the difference between the first plasma emission intensity and the second plasma emission intensity exceeding a first threshold; and
determining that the dry cleaning should be terminated in response to a state in which the difference between the first plasma emission intensity and the second plasma emission intensity is within a normal range having continued for a first predetermined period of time.

5. The method according to claim 1, wherein the determining of the state of the inner wall includes determining that seasoning should be terminated in response to a state in which the difference between the first plasma emission intensity and the second plasma emission intensity is within a normal range having continued for a second predetermined period of time.

6. The method according to claim 1, wherein the detector is configured to change a direction of an optical axis of the detector; and
the first light and the second light are detected, by changing the direction of the optical axis of the detector.

7. The method according to claim 1, wherein the detector includes a first detector having a first optical axis passing through the plasma generating region, and a second detector having a second optical axis that reaches the inner wall of the plasma processing apparatus without passing through the plasma generating region;
the first plasma emission intensity is detected by the first detector; and
the second plasma emission intensity is detected by the second detector.

8. The method according to claim 1, wherein
the at least one second plasma emission intensity includes a plurality of second plasma emission intensities, the respective second plasma emission intensities being intensities of different light incident on the detector from different points on the inner wall of the plasma processing apparatus without passing through the plasma generating region; and
the state of the inner wall of the plasma processing apparatus is determined based on a plurality of differences each being a difference between the first plasma emission intensity and a corresponding second plasma emission intensity of the second plasma emission intensities, or based on a plurality of ratios each being a ratio between the first plasma emission intensity and a corresponding second plasma emission intensity of the second plasma emission intensities.

9. The method according to claim 8, wherein the determining of the state of the inner wall includes
determining that dry cleaning should be started in response to at least one of the plurality of differences exceeding a first threshold; and
determining that the dry cleaning should be terminated in response to a state in which all of the plurality of differences are within a normal range having continued for a first predetermined period of time.

10. The method according to claim 8, wherein wherein the determining of the state of the inner wall includes
determining that seasoning should be terminated in response to a state in which all of the plurality of differences are within a normal range having continued for a second predetermined period of time.

11. A plasma processing apparatus comprising:
a processing vessel;
a detector configured to measure emission intensity of a plasma in the processing vessel; and
a controller configured
to acquire a first plasma emission intensity from the detector, the first plasma emission intensity being an intensity of first light incident on the detector through a plasma generating region;
to acquire at least one second plasma emission intensity from the detector, the second plasma emission intensity being an intensity of second light incident on the detector from an inner wall of the plasma processing apparatus, without passing through the plasma generating region; and
to determine a state of the inner wall of the plasma processing apparatus based on a difference between the first plasma emission intensity and the second plasma emission intensity, or based on a ratio between the first plasma emission intensity and the second plasma emission intensity.
